(19) United States
(12) Patent Application Publication
(10) Pub. No.: US 2026/0267611 A1
(43) Pub. Date: Sep. 10, 2026

(54) A MEMORY COMPUTING DEVICE, A METHOD OF OPERATING THE SAME AND AN AI SYSTEM INCLUDING THE SAME

(71) Applicant: The University Court of the University of Edinburgh, Edinburgh (GB)

(72) Inventors: Shady Onsey Haleem Rizkalla, Edinburgh (GB); Themistoklis Prodromakis, Edinburgh (GB)

(21) Appl. No.: 19/162,924

(22) PCT Filed: Feb. 27, 2024
(86) PCT No.: PCT/GB2024/050524

§ 371 Date: Sep. 5, 2025

(30) Foreign Application Priority Data
Mar. 7, 2023 (GR) 20230100193
Apr. 18, 2023 (GB) 2305662.5

(51) Int. Cl. G06F 7/58; G06F 13/10

(52) U.S. Cl. CPC G06F 7/58; G06F 13/10; G06F 2213/40

(57) ABSTRACT

A memory computing device includes a bitcell array having a plurality of bitcells each connected to a respective wordline and bitline; an address decoder connected to the bitcell array; and peripheral circuitry connected to the bitcell array, having pre-charging and pre-discharging circuitry, sensing circuitry and output circuitry. The address decoder is configured to receive an address for a wordline and to activate the wordline corresponding to the address. The peripheral circuitry is configured to: pre-charge or pre-discharge a bitline in the bitcell array using the pre-charging and pre-discharging circuitry; sense the bitline using the sensing circuitry; receive a stochastic multiplier as input data for multiplication with read bitcell data in the bitcell array that constitutes a stochastic multiplicand; perform, by the peripheral circuitry of the memory computing device, a digital stochastic multiplication between the input data and the read bitcell data; and output a result of the stochastic multiplication.

### FIELD OF DISCLOSURE

The disclosure relates to a memory computing device, a method of operating the memory computing device and an Artificial Intelligence (AI) system including the memory computing device.

### BACKGROUND

Applications of Artificial Intelligence (AI), and especially Deep Neural Networks (DNNs), are dominating the technology sector with ever increasing performance demands. Such data-intensive applications not only have to handle huge amounts of data but also increasing degrees of computational complexity. Conventional Von Neumann architectures are struggling to meet these new challenges due to the required data-movement causing a performance bottleneck. Furthermore, conventional binary systems suffer from poor performance in handling the high computational complexity of vector-matrix multiplication, which forms the computational core of DNNs.

In “Compute Caches” by S. Aga, S. Jeloka, A. Subramaniyan, S. Narayanasamy, D. Blaauw and R. Das (2017 IEEE International Symposium on High Performance Computer Architecture (HPCA), 2017, pp. 481-492, doi: 10.1109/HPCA.2017.21), the conventional digital bitline computing approach is utilised for a binary system to obtain bitwise AND and NOR operations between two memory wordlines. However, this approach requires a second address decoder so as to activate two wordlines simultaneously, and therefore it consumes more area and energy than for a system with a single address decoder. Moreover, to perform binary addition and multiplication, the memory has to have a compute logic stack in the peripheral circuits, which increases energy consumption and decreases the overall density of the memory.

In “Stochastic-HD: Leveraging Stochastic Computing on the Hyper-Dimensional Computing Pipeline” by Justin Morris, Yilun Hao, Saransh Gupta, Behnam Khaleghi, Baris Aksanli, and Tajana Rosing (Frontiers in Neuroscience, Vol. 16, 2022, DOI=10.3389/fnins.2022.867192, ISSN=1662-453X), a Resistive Random-Access Memory (RRAM)-based Content-Addressable Memory (CAM) is utilised to target the stochastic hyper-dimensional domain. This system performs a search operation to get the best match between inputs and bitcells using a current-based accumulation of the stochastic multiplication. Notwithstanding the analogue accumulation, CAMs are less dense and occupy a larger area than conventional (digital) memories due to requiring a large number of control signals and double the number of sense-amplifiers. In particular, this approach uses two RRAM devices per bitcell to save the data and its complementary, which leads to a high energy consumption and large footprint. This CAM-based design also has scalability and timing issues due to the current-based accumulation, which limits the on-chip capacity and the overall density of the CAM.

It is therefore an aim of the present disclosure to provide a memory computing device that address one or more of the problems above or at least provides a useful alternative.

### SUMMARY

In general, this disclosure proposes to overcome the above problems by utilising the inherent AND behaviour of a conventional memory read operation to perform fully digital stochastic multiplication (replicating a bitwise AND operation) between the inputs and the bitcells with a marginal area overhead and without any scalability issues.

According to one aspect of the present disclosure, there is provided a memory computing device comprising:
a bitcell array comprising a plurality of bitcells, each bitcell being connected to a respective wordline and bitline;
an address decoder connected to the bitcell array; and
peripheral circuitry connected to the bitcell array, the peripheral circuitry comprising pre-charging and pre-discharging circuitry, sensing circuitry, write drivers and output circuitry;
wherein the address decoder is configured to receive an address for a wordline in the bitcell array and to activate the wordline corresponding to the address; and
wherein the peripheral circuitry is configured to:
pre-charge or pre-discharge a bitline in the bitcell array using the pre-charging and pre-discharging circuitry;
sense the bitline using the sensing circuitry;
receive a stochastic multiplier as input data for multiplication with read bitcell data in the bitcell array, wherein the read bitcell data constitutes a stochastic multiplicand;
perform, by the peripheral circuitry of the memory computing device, a digital stochastic multiplication between the input data and the read bitcell data; and
output a result of the stochastic multiplication.

Thus, the disclosure provides a memory computing device configured to perform, by the peripheral circuitry of the memory computing device, a digital stochastic multiplication between the input data and the read bitcell data. This provides significant advantages, particularly in the context of data processing demands of neural networks.

In particular, the memory computing device mitigates the Von Neumann bottleneck by processing the data where it exists in memory. The memory computing device may also dramatically decrease the computational complexity of a vector-matrix multiplication by migrating to the stochastic domain. Unlike for a conventional bitline computing approach, the present memory computing device has a minimal hardware overhead. More specifically, the present memory computing device does not require additional address decoders because it does not activate two wordlines simultaneously to do the bitline computing. This should lead to denser on-chip memory arrays with smaller energy footprints. In contrast to analogue in-memory computing, the present memory computing device inherits the same robustness, scalability, and productivity of the digital domain whilst maintaining the same computational simplicity of the analogue domain.

Accordingly, the present memory computing device addresses the mitigation of the main bottlenecks and challenges of modern AI hardware, while avoiding the major drawbacks of other proposed solutions. Furthermore, the structure of the memory computing device opens the door for the building of gigantic on-chip memories that can be easily reconfigured at runtime into massive parallel vector/matrix-matrix multiplication accelerators with only a marginal area overhead.

In addition, energy benchmarking tests indicate that the proposed approach is energy efficient because the difference between the conventional memory read energy and the in-memory stochastic multiplication energy of the proposed memory computing device is negligible.

The proposed memory computing device may be considered to constitute an on-the-fly in-memory stochastic multiplication accelerator as the computation can be performed quickly within the memory itself (including the peripheral circuitry), without moving data prior to multiplication and without significantly changing the memory architecture.

It will be understood that stochastic computing (SC), which includes stochastic multiplication, combines the best properties of analogue and digital domains. In particular, SC is a low energy cost alternative to binary computing. It performs operations using probability instead of arithmetic and it therefore allows for noise and uncertainty to tolerate transient errors in input data.

The peripheral circuitry may be configured to mask the read bitcell data in the bitcell array to logic value 0 when the input data is 0.

The pre-charging and pre-discharging circuitry may be configured to perform the stochastic multiplication.

The pre-charging and pre-discharging circuitry may be configured to pre-discharge the bitline of the bitcell such that the read bitcell data has a logic value 0 when the input data is 0.

The peripheral circuitry may be configured to pre-charge the bitline of the bitcell for a conventional read operation, when the input data is 1.

The sensing circuitry may be configured to perform the stochastic multiplication.

The sensing circuitry may be configured to pull down the read bitcell data to logic value 0 when the input data is 0.

The output circuitry may be configured to perform the stochastic multiplication.

The output circuitry may be configured to reset the read bitcell data to logic value 0 when the input data is 0.

The peripheral circuitry may comprise one or more multiplexers operable to select a mode of operation of the memory computing device to one of a stochastic multiplication mode wherein the result of the stochastic multiplication is output and a conventional read mode wherein the read bitcell data in the bitcell array is output.

The use of a multiplexer allows the memory computing device to be easily reconfigured (e.g. switched) from operating as a conventional memory in which a conventional read operation may be carried out to operating as a novel memory computing device in which the stochastic multiplication is carried out, for example, as may be required for a DNN application. Notably, the use of one or more multiplexers adds minimal peripheral circuit overhead.

The one or more multiplexers may be operable to prevent the input data from being used for stochastic multiplication when the conventional read mode is selected.

In a particular embodiment, each bitcell in the memory computing device may comprise only one RRAM element—contrary to two RRAM elements being required in the prior art. However, other memory technologies may be used.

According to a second aspect of this disclosure, there is provided a computer-implemented method of operating a memory computing device as a stochastic multiplier comprising:
performing a read operation on a bitcell array, the read operation comprising:
pre-charging a bitline (and pre-discharging a bitline bar for single-ended bitcells) in the bitcell array;
activating a wordline in the bitcell array; and
sensing the bitline;
receiving, in peripheral circuitry of the memory computing device, a stochastic multiplier as input data for multiplication with read bitcell data in the bitcell array, wherein the read bitcell data constitutes a stochastic multiplicand;
performing, by the peripheral circuitry of the memory computing device, a digital stochastic multiplication between the input data and the read bitcell data; and
outputting a result of the stochastic multiplication.

The computer-implemented method may be performed by a memory computing device in accordance with any of the above.

According to a third aspect of this disclosure, there is provided a non-transitory computer-readable storage medium comprising instructions which, when executed by a computer cause the computer to perform the method above.

According to a fourth aspect of this disclosure, there is provided an artificial intelligence (AI) system comprising at least one memory computing device in accordance with any of the above.

The AI system is not limited to a particular application. However, the markets for image recognition and natural language processing using AI systems are currently experiencing upward trends and the present memory computing device may be advantageous for these (and other) applications.

Prior art memory computing devices tend to fall into one the following two categories:
1. A digital approach with a large hardware overhead and a potentially slow performance; or
2. An analogue approach suffering from low density and with scalability and variability issues.

Compared to such known systems, the present memory computing device disclosed here has the following advantages:
1. Compatibility and ease of integration with existing memory devices;
2. Increased performance;
3. Low energy consumption;
4. Small hardware overhead;
5. Small footprint;
6. Robustness;
8. Scalability;
9. Computational simplicity; and
10. Ease of reconfiguration.

Finally, the present memory computing device disclosed here utilises a novel approach at least in exploiting the inherent AND nature of a memory read operation (e.g. between the bitline and the bitcell) to perform stochastic multiplication.

At least some of the above and other features of the invention are set out in the claims.

These and other aspects will be apparent from the embodiments described in the following. The scope of the present disclosure is not intended to be limited by this summary nor to implementations that necessarily solve any or all of the disadvantages noted.

Any features described in relation to one aspect of the disclosure may be applied to any one or more other aspect of the disclosure.

### BRIEF DESCRIPTION OF THE PREFERRED EMBODIMENTS

Some embodiments of the disclosure will now be described by way of example only and with reference to the accompanying drawings, in which:

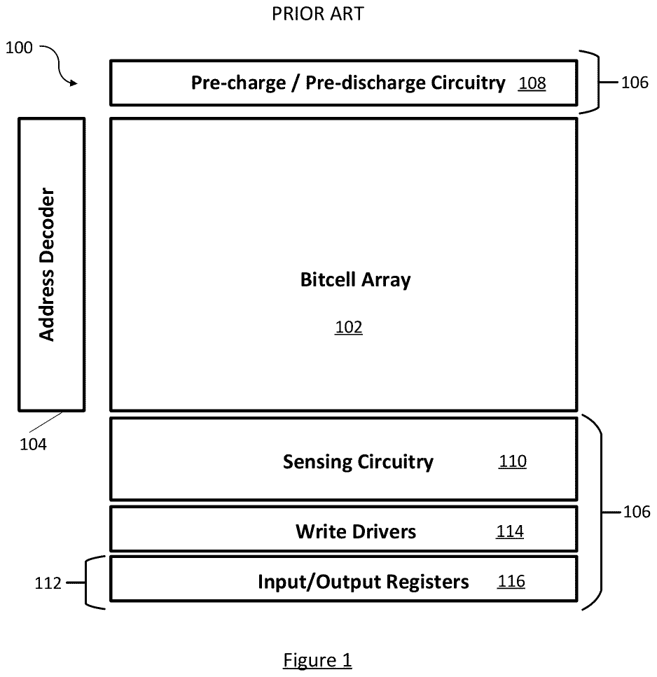

FIG. 1 shows a block diagram for a conventional memory device;

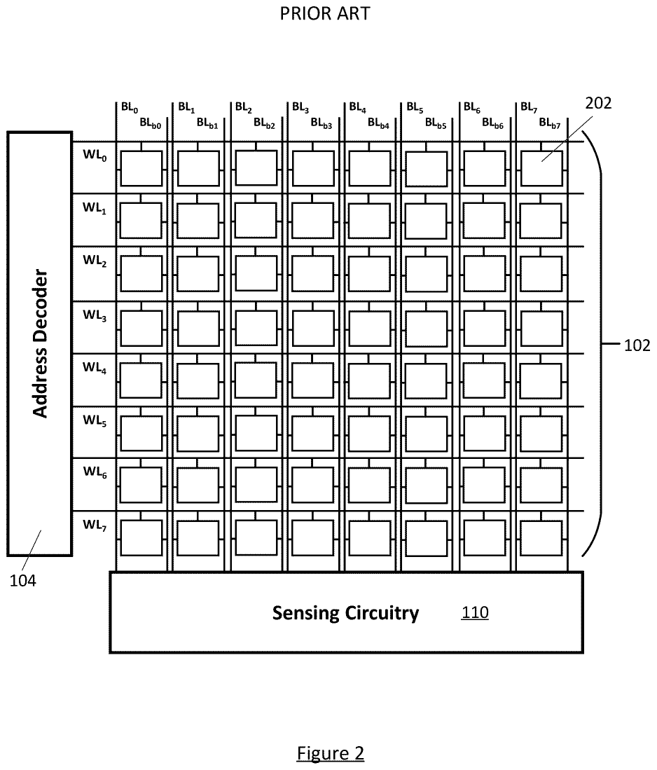

FIG. 2 shows a block diagram showing more details for some of the components in the conventional memory device of FIG. 1;

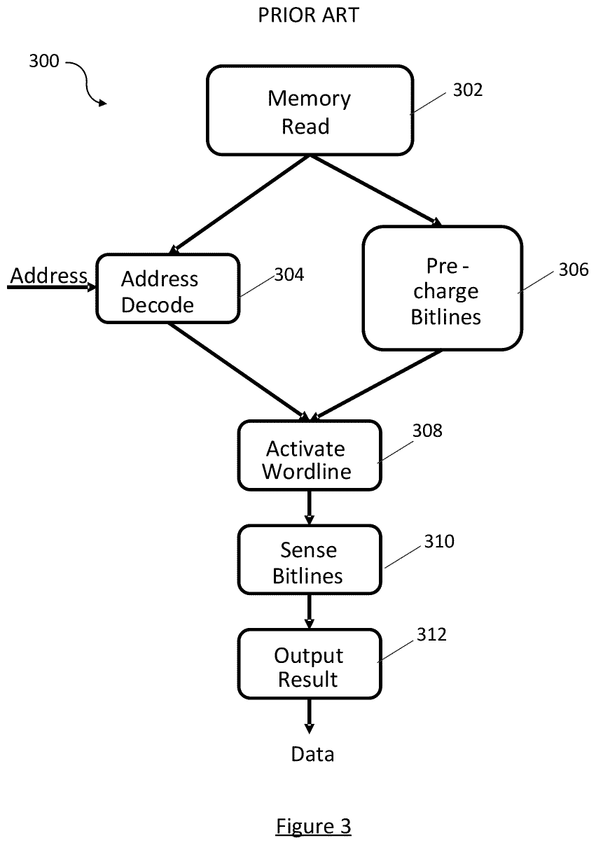

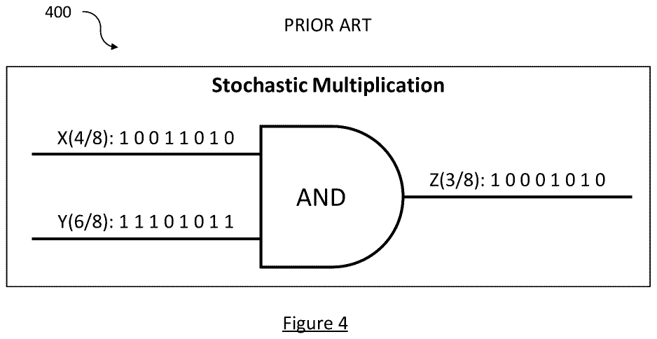

FIG. 3 shows a flow diagram for a conventional read operation for the conventional memory device of FIG. 1;

FIG. 4 shows a logic diagram illustrating a known stochastic multiplication technique;

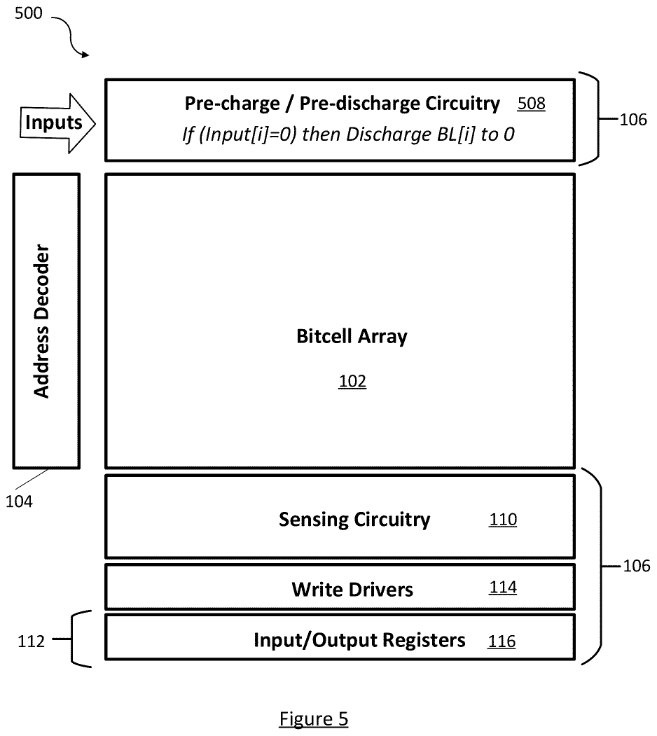

FIG. 5 Shows a Block Diagram for a Memory Computing Device in Accordance With the present disclosure;

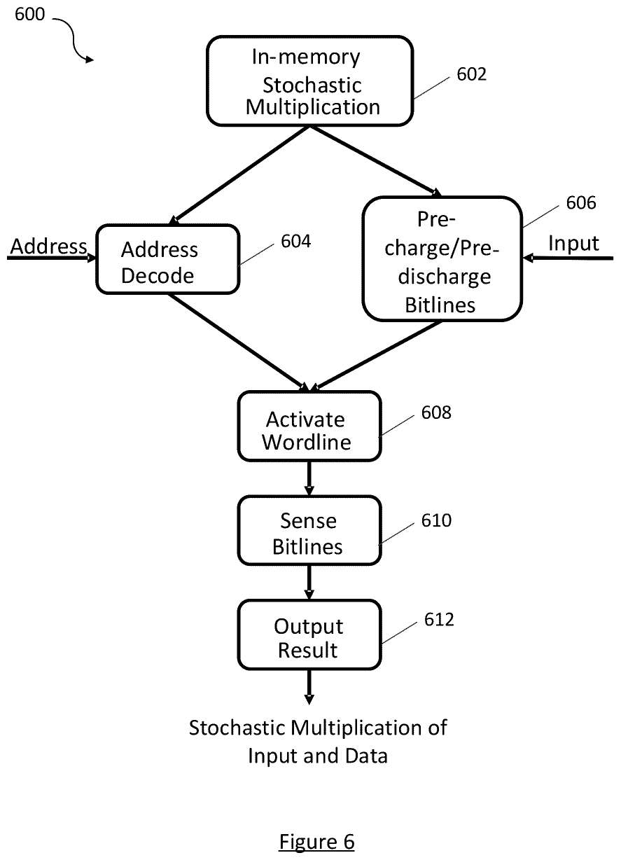

FIG. 6 shows a flow diagram for a stochastic multiplication operation for the memory computing device of FIG. 5;

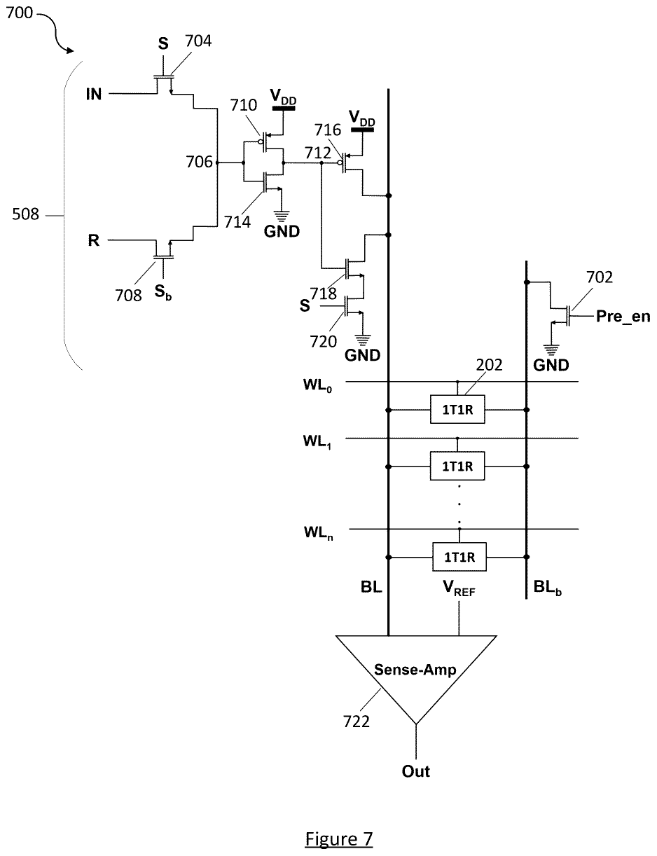

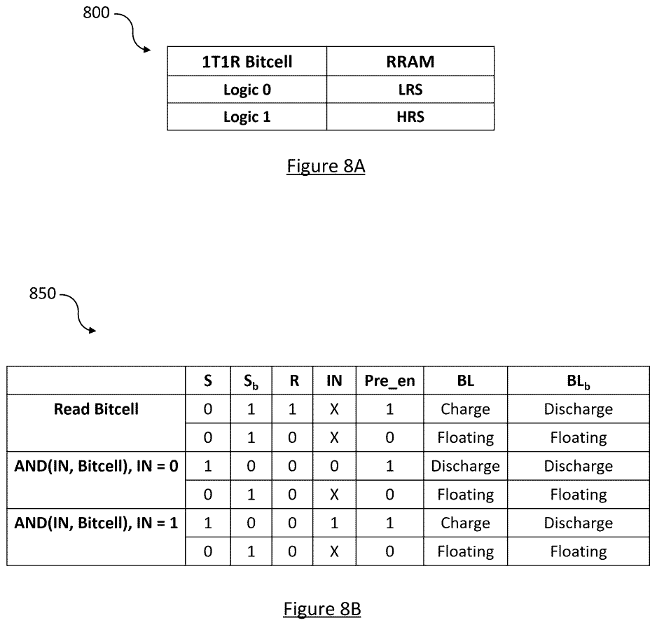

FIG. 7 shows a circuit diagram for components of the memory computing device of FIG. 5;

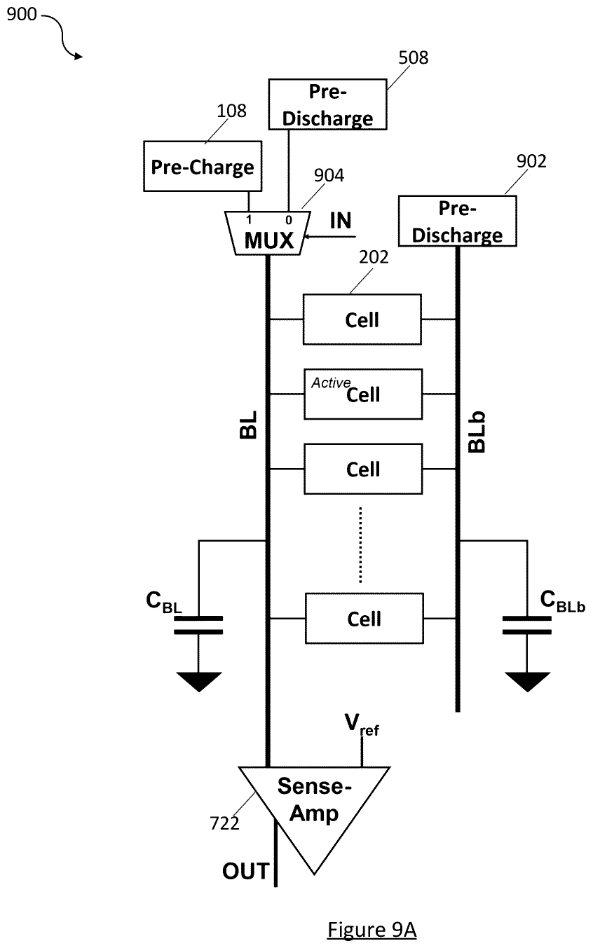

FIG. 8A shows a table relating logic levels to RRAM properties for the bitcells in the circuit of FIG. 7;

FIG. 8B shows a table illustrating values for various components in the circuit of FIG. 7 under different operating modes;

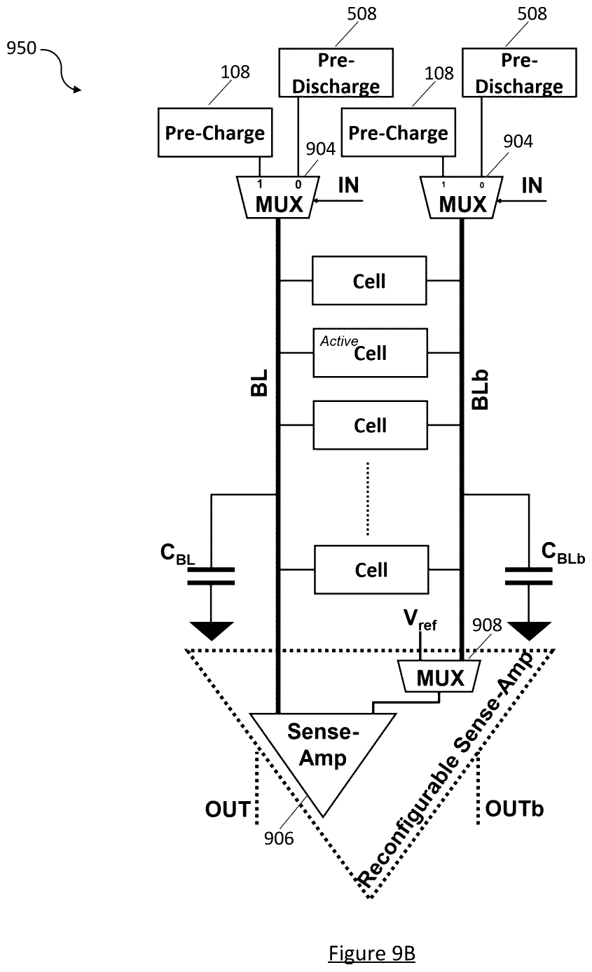

FIG. 9A shows a block diagram for components of the memory computing device of FIG. 5 including single-ended bitcells;

FIG. 9B shows a block diagram for components of the memory computing device of FIG. 5 including differential bitcells;

FIG. 10 shows a table illustrating a stochastic multiplication output for various memory array data and input data;

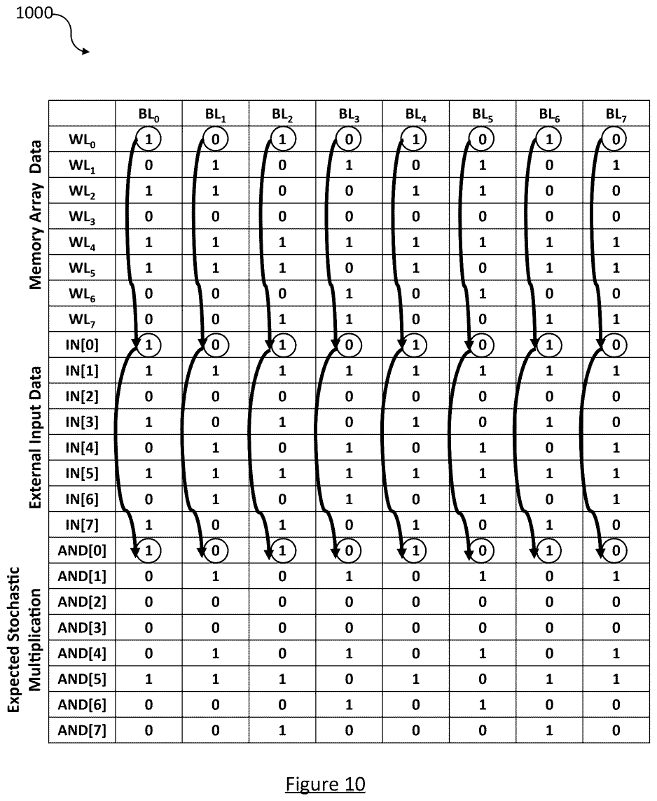

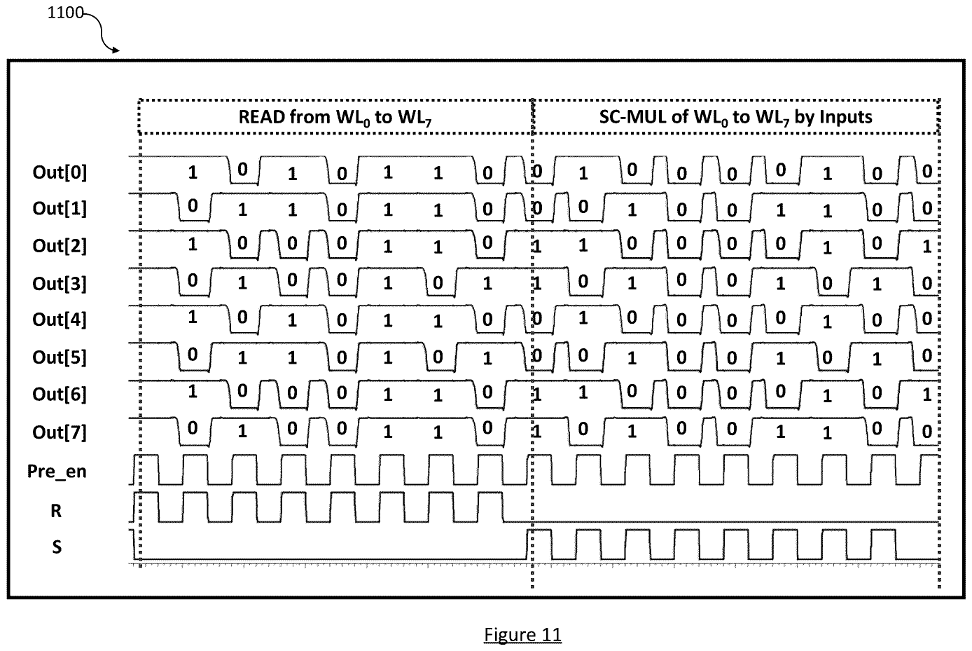

FIG. 11 shows a simulation diagram illustrating the output for 8 memory read operations and 8 in-memory stochastic multiplication operations using the data and inputs in FIG. 10;

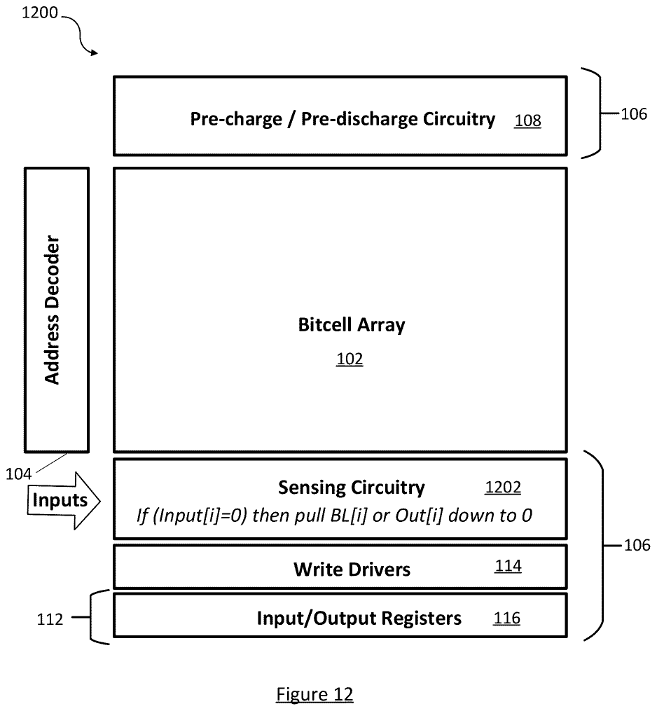

FIG. 12 shows a block diagram for a further memory computing device in accordance with the present disclosure;

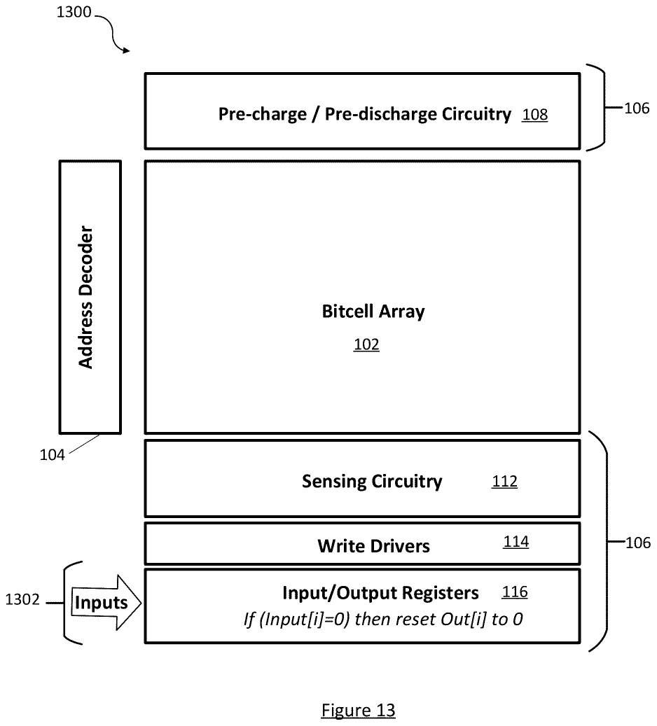

FIG. 13 shows a block diagram for another memory computing device in accordance with the present disclosure;

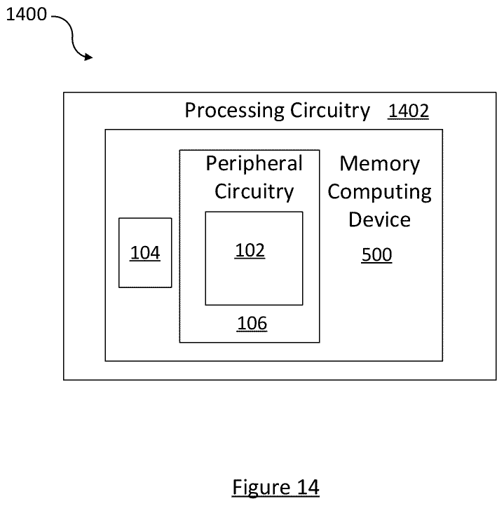

FIG. 14 shows a block diagram for an Al system in accordance with the present disclosure.

### DETAILED DESCRIPTION OF THE PREFERRED EMBODIMENTS

Generally speaking, the disclosure provides a memory computing device that can be operated as an on-the-fly in-memory stochastic multiplication accelerator. The solution utilises the inherent AND behaviour of a conventional memory read operation to perform fully digital stochastic multiplication (replicating a bitwise AND operation) between external inputs and bitcell data with a marginal area overhead and without any scalability issues.

Some examples of the solution are given in FIGS. 5 to 13, with background to the invention explained in connection with FIGS. 1 to 4.

FIG. 1 shows a block diagram for a conventional memory device 100 comprising a bitcell array 102, an address decoder 104 and peripheral circuitry 106.

As shown in FIG. 2, the bitcell array 102 comprises a plurality of bitcells 202, each bitcell 202 being connected to a respective wordline WLₙ, bitline BLₖ and bitline bar BL_{bk}. In the example shown, there are 8 wordlines WL₀ to WL₇, 8 bitlines BL₀ to BL₇ and 8 bitline bars BL_{b0} to BL_{b7}.

The address decoder 104 is connected to the bitcell array 102 and configured to receive an address for a wordline WLₙ in the bitcell array 102 and to activate the wordline WLₙ corresponding to the address.

Referring back to FIG. 1, the peripheral circuitry 106 is connected to the bitcell array 102 and includes pre-charging and pre-discharging circuitry 108, sensing circuitry 110, output circuitry 112 and write drivers 114. The output circuitry 112 comprises input/output registers 116. The write drivers 114 will be configured to write data to the bitcells 202 in a conventional manner.

The pre-charging and pre-discharging circuitry 108 is configured to pre-charge a bitline BLₖ and to pre-discharge a bitline bar BL_{bk} in the bitcell array 102.

The sensing circuitry 110 is configured to sense a bitline BLₖ.

The output circuitry 112 is configured to output a result of a read operation. The output can be written in the input/output registers 116.

FIG. 3 shows a flow diagram 300 for a conventional read operation for the conventional memory device 100 of FIGS. 1 and 2.

In step 302, a memory read instruction is sent by a memory controller to the address decoder 104 and the pre-charging and pre-discharging circuitry 108. In a step 304, an address for a wordline WLₙ is received from the memory controller and decoded by the address decoder 104. In a step 306, the pre-charging and pre-discharging circuitry 108 pre-charges the bitlines BLₖ and pre-discharges the bitline bars BL_{bk} in the bitcell array 102.

In a step 308, the address decoder 104 activates the wordline WLₙ in the bitcell array 102. In a step 310, the sensing circuitry 110 senses the bitlines BLₖ. In a step 312, the data sensed by the sensing circuitry 110 is output as a result. The result may be written to an input/output register 116 or may be transmitted (e.g. to a processor or other circuitry) as an output from the memory device 100.

In accordance with the present disclosure, a memory computing device is described which expands the operation of the above described memory device 100 to perform in-memory stochastic multiplication.

By way of background, FIG. 4 shows a logic diagram illustrating a known stochastic multiplication technique 400. Stochastic numbers are represented by random or pseudo-random bitstreams of ones and zeros which are interpreted as probabilities. For example, a first stochastic number X may comprise the bit series 10011010 which includes 4 out of 8 bits having a logic value of 1. Accordingly, X corresponds to 4/8 bits which can be mapped to a probability of 0.5. A second stochastic number Y may comprise the bit series 11101011 which includes 6 out of 8 bits having a logic value of 1. Accordingly, Y corresponds to 6/8 bits which can be mapped to a probability of 0.75.

Stochastic multiplication can be performed by a bitwise AND operation between X (4/8) and Y (6/8) producing an output Z of 10001010 (3/8). This can be mapped to the equivalent probabilities where X is 0.5 and Y is 0.75 so that the multiplication output is 0.375, which is equivalent to 3/8. Accordingly, stochastic multiplication will result from a bitwise AND operation between two stochastic numbers.

FIG. 5 shows a block diagram for a memory computing device 500 in accordance with the present disclosure. The memory computing device 500 is similar to the memory device 100 and therefore a description of similar components will not be repeated. The key difference over the memory device 100 is that the peripheral circuitry 106 is configured to exploit the inherent AND nature of the read operation to perform digital stochastic multiplication. In the memory computing device 500, the pre-charging and pre-discharging circuitry 508 is additionally configured for a stochastic multiplication mode with minimal peripheral circuit overhead.

The memory computing device 500 depends on the conventional bitline BLₖ discharging read approach. The bitline BLₖ is pre-charged as normal and then disconnected for a read operation. If the bitline BLₖ discharges below a threshold it is read as logic 0, but if it does not discharge it is read as logic 1.

Furthermore, the memory computing device 500 receives digital inputs IN (which are stochastic multipliers) to the pre-charging and pre-discharging circuitry 108 to control the pre-charging and pre-discharging process based on a logic value of the input IN. If the input IN is 1, the bitline BLₖ is pre-charged as a normal read operation and the activated bitcell 202 is read. This corresponds to a bitwise AND operation between the input IN (stochastic multiplier) and the data in the activated bitcell 202 (which is a stochastic multiplicand) causing the output to be 1 if the data is 1 and 0 if the data is 0. If the input IN is 0, the bitline BLₖ is pre-discharged (to 0) and the activated bitcell 202 is always read as logic 0 regardless the value of data in the bitcell 202, which also corresponds to the bitwise AND operation when an input is 0.

The inputs IN and the data in the bitcells 202 are unipolar stochastic numbers, meaning that the bitwise AND operation represents stochastic multiplication for the stochastic numbers. When different inputs IN are forwarded to all bitcells 202 within the activated wordline WLₙ in the bitcell array 102, parallel stochastic multiplication operations are performed on-the-fly during what would otherwise be a normal read operation. The outputs from the stochastic multiplication are sensed by the sensing circuitry 110 and output via the output circuitry 112 in the manner of a conventional read operation.

FIG. 6 shows a flow diagram for a stochastic multiplication operation for the memory computing device 500 of FIG. 5.

In step 602, a stochastic multiplication instruction is sent by a memory controller to the address decoder 104 and the pre-charging and pre-discharging circuitry 108. In a step 604, an address for a wordline WLₙ is received from the memory controller and decoded by the address decoder 104. In a step 606, the pre-charging and pre-discharging circuitry 508 pre-charges or pre-discharges the bitlines BLₖ in the bitcell array 102 according to the inputs IN. If the input IN is 1, the bitline BLₖ is pre-charged as a normal read operation. If the input IN is 0, the bitline BLₖ is pre-discharged (to 0).

In a step 608, the address decoder 104 activates the wordline WLₙ in the bitcell array 102. In a step 610, the sensing circuitry 110 senses the bitlines BLₖ. In a step 612, the 1 or 0 sensed by the sensing circuitry 110 is output as a result of the stochastic multiplication of the input IN and the data in the bitcell 202. The result may be written to an input/output register 116 or may be transmitted (e.g. to a processor or other circuitry) as an output from the computing device 500.

As described above, when the input IN is 1, the bitline BLₖ is pre-charged as a normal read operation and the activated bitcell 202 is read. However, when the input IN is 0, the bitline BLₖ is pre-discharged to read logic 0 regardless of the value of data in the bitcell 202. As such, the pre-charging and pre-discharging circuitry 508 facilitates an in-memory bitwise AND operation between the inputs IN and the data in the bitcells 202, effectively masking the read bitcell data in the bitline BLₖ when the input IN is 0.

FIG. 7 shows a circuit diagram 700 for components of the memory computing device 500 of FIG. 5 for a bitcell column in the bitcell array 102, including one transistor one resistor (e.g. Memristor) (1T1R) bitcells 202. The bitcell column includes a bitline BL and a complementary bitline bar BL_{b} connected to each bitcell 202. Wordlines WL₀ to WLₙ are also connected, respectively, to each bitcell 202. Although not all are shown in the present example, there are 8 wordlines WL₀ to WL₇ and therefore n is 8 as an example for illustration. However, n can be any reasonable number.

In FIG. 7, the bitcells 202 are single-ended and therefore only the bitline BL is controlled by the input IN while the bitline bar BL_{b} is pre-discharged to 0. Accordingly, the bitline bar BL_{b} is connected to a drain of a transistor 702 having a source connected to ground GND and a gate connected to a pre-discharge enable (Pre_en) control signal for pre-discharging the BL_{b} (to 0).

The bitline BL is connected to pre-charging and pre-discharging circuitry 508. A first transistor 704 has a drain connected to the input IN, a source connected to a node 706 and a gate connected to a select signal S. A second transistor 708 has a drain connected to a read signal R, a source connected to the node 706 and a gate connected to a complementary select bar signal S_{b}. A third transistor 710 has a gate connected to node 706, a source connected to a supply voltage V_{DD}, and a drain connected to a node 712. A fourth transistor 714 has a gate connected to node 706, a drain connected to the node 712, and a source connected to ground GND. A fifth transistor 716 has a gate connected to node 712, a source connected to the supply voltage V_{DD}, and a drain connected to the bitline BL. A sixth transistor 718 has a gate connected to node 712, a source connected to a drain of a seventh transistor 720, and a drain connected to the bitline BL. The seventh transistor 720 has a drain connected to the source of the sixth transistor 718, a source connected to ground GND and a gate connected to the select signal S.

The bitline BL is connected to a sense-amplifier 722 of the sensing circuitry 110. A reference voltage V_{REF} is also input to the sense-amplifier 722 for comparison with the voltage on the bitline BL. If the bitline BL voltage is greater than V_{REF} a value of 1 will be output (Out). However, if the bitline BL voltage is less than V_{REF} a value of 0 will be output (Out).

As shown in the table 800 in FIG. 8A, when the 1T1R bitcells 202 in FIG. 7 comprise RRAMs (Memristors), a low resistance state LRS will be considered as logic 0 while a high resistance state HRS will be considered as logic 1.

FIG. 8B shows a table 850 illustrating values for various components in the circuit 700 of FIG. 7 under different operating modes. For example, for a conventional read operation, the read signal R will be 1 and the input IN will be disregarded (X) because the select signal S will be 0 and the select bar S_{b} will be 1. The pre-discharge enable (Pre_en) control signal will be 1 to discharge the bitline bar BL_{b} and the bitline BL will charge so that data from the bitcell can be read. When the read signal R is 0, the bitline BL will be disconnected from the pre-charge/pre-discharge circuitry 508 (i.e. it will be floating state) and when the pre-discharge enable (Pre_en) control signal is 0, the bitline bar BL_{b} will be disconnected from the pre-discharge circuitry (i.e. it will be in a floating state) and the data in the bitcell is read by the sense-amplifier 722.

For a stochastic multiplication operation (i.e. a bitwise AND operation between the input IN and the data in the bitcell 202), the read signal R will be 0, the select signal S will be 1 and the select bar signal S_{b} will be 0. Consequently, the input IN controls the pre-charging and pre-discharging circuitry of the bitline BL. When the input IN is 0 the bitline BL will discharge (e.g. to 0 or another lower voltage). However, when the input IN is 1 the bitline BL will charge and data in the bitcell can be read. The pre-discharge enable (Pre_en) control signal will be 1 to discharge the bitline bar BL_{b}. When the select signal S is 0 and the select bar signal S_{b} is 1, the input IN will be disregarded (X), and the bitline BL and the bitline bar BL_{b} will float because the read signal R and the pre-discharge enable (Pre_en) control signal are 0. The output will be the stochastic multiplication (bitwise AND) between the input IN and the data in the bitcell.

FIG. 9A shows a schematic diagram 900 for components of the memory computing device 500 of FIG. 5 including single-ended bitcells 202. As for FIG. 7, only the bitline BL is controlled by the input IN while the bitline bar BL_{b} is pre-discharged to 0 using circuitry 902 (similar to that shown in FIG. 7). In this case, a multiplexer 904 is included in the peripheral circuitry 106 to allow the memory computing device 500 to be reconfigured to operate in either a conventional read mode (using only conventional pre-charging and pre-discharging circuitry 108) or the stochastic multiplication mode (using pre-charging and pre-discharging circuitry 508). Capacitors C_{BL} and C_{BLb} are parasitic capacitances connected, respectively, to the bitline BL and bitline bar BL_{b}.

In this case, the single-ended (1T1R) bitcells 202 occupy a smaller footprint than those in FIG. 9B. Accordingly, this emerging technology offers a higher on-chip data density for the memory computing device 500.

FIG. 9B shows a schematic diagram 950 for components of the memory computing device 500 of FIG. 5 including differential bitcells 202 (which may take the form of 6 transistor (6T) complementary metal-oxide-semiconductor (CMOS) static random access memory (SRAM) cells). In this case, the input IN controls both the bitline BL and the complementary bitline bar BL_{b} in the same way as described previously for just the bitline BL.

Two multiplexers 904 are included in the peripheral circuitry 106 to allow the memory computing device 500 to be reconfigured to operate in either a conventional read mode (using conventional pre-charging and pre-discharging circuitry 108) or the stochastic multiplication mode (using the pre-charging and pre-discharging circuitry 508).

In this case, there is also a reconfigurable sense-amplifier 906 including a multiplexer 908 to allow selection between V_{REF} and the bitline bar BL_{b}.

In operation, the bitline BL is pre-charged to V_{DD} if the input IN is 1, which leads to the conventional read operation. For example, if the bitcell 202 data has the value of 1(0 ), the sense amplifier 906 will read logic value 1(0 ), which corresponds to a bitwise AND operation. However, if the input IN is 0, the bitline BL is pre-discharged to 0 and the sense amplifier 906 will always read 0 regardless of the data value in the bitcell 202, which also corresponds to a bitwise AND operation. The input IN is also forwarded to the bitline bar BL_{b} in this case, to avoid any data-disturbance while doing the AND operation.

FIG. 10 shows a table 1000 illustrating stochastic multiplication output for various combinations of memory array data and input data values. In this example, there are 8 wordlines WL₀ to WL₇ and 8 bitlines BL₀ to BL₇ but in other examples other numbers of wordlines and/or bitlines may be used. The table 1000 shows a balanced distribution of values 1 and 0 in each bitcell 202 of the memory array 102. These 1 and 0 values are generated (without randomness) only for testing the AND behaviour of the stochastic multiplication.

In addition, a balanced set of values 1 and 0 are illustrated as input data IN[0] to IN[7] for stochastic multiplication with each bitcell data value. These input data values are also generated (without randomness) only for testing the AND behaviour of the stochastic multiplication.

The result of the stochastic multiplication is illustrated in the rows AND[0] to AND[7].

For example, when WL₀ and BL₀ are selected, the data value is 1 and the corresponding Input value IN[0] is 1 resulting in a stochastic multiplication value of AND[0] that is also 1.

FIG. 11 shows a simulation diagram illustrating the output Out[0] to Out[7] for 8 memory read operations and 8 in-memory stochastic multiplication operations using the data and inputs in FIG. 10. FIG. 11 also illustrates the state of the pre-discharge enable (Pre_en) control signal, the read signal R and the select signal S from FIG. 7. Notably, the results in FIG. 11 correspond to the stochastic multiplication values AND[0] to AND[7] of FIG. 10 when output consecutively for a given bitline BL₀ to BL₇. In other words, a row in FIG. 10 corresponds to a column in FIG. 11.

FIG. 12 shows a block diagram for a further memory computing device 1200 in accordance with the present disclosure.

In this case, instead of the pre-charging and pre-discharging circuity 508 of FIG. 5 being configured to perform digital stochastic multiplication between the input data and the read bitcell data, the sensing circuitry 1202 in FIG. 12 is configured to perform the stochastic multiplication.

Accordingly, in this case, masking the value of the bitcell 202 to read logic 0 when the input IN is 0 can be done by forcing the sensing circuitry 1202 to logic 0, without pre-discharging the bitline BL.

FIG. 13 shows a block diagram for another memory computing device 1300 in accordance with the present disclosure.

In this case, instead of the pre-charging and pre-discharging circuity 508 of FIG. 5 being configured to perform digital stochastic multiplication between the input data and the read bitcell data, the output circuitry 1302 in FIG. 13 is configured to perform the stochastic multiplication.

Accordingly, in this case, forcing the output to read logic 0 when the input IN is 0 can be done by resetting the output to logic 0 using the output circuitry 1302.

In fact, forcing the output of the memory computing device to a constant logic (e.g. 0) conditional to the input logic value (0) to mask the read operation can be implemented at any peripheral circuit level to achieve the present in-memory stochastic multiplication.

FIG. 14 shows a block diagram for an AI system 1400 in accordance with the present disclosure. The AI system 1400 comprises processing circuitry 1402 comprising the memory computing device 500 of FIG. 5. However, in other examples, the AI system 1400 may comprise the memory computing device 1200 of FIG. 12 or the memory computing device 1300 of FIG. 13.

The processing circuitry 1402 may comprise a DNN. However, the application of the AI system 1400 is not limited.

Embodiments of the present disclosure can be employed in many different applications including, for example, image recognition and natural language processing.

The proposed design has been simulated using commercial 180 nm technology, in-house models for the RRAM devices, and industrial-grade computer-aided design (CAD) tools. The schematic simulations prove the functionality of the two modes of operation: the conventional memory operation and the in-memory stochastic multiplication are 100% operationally correct. The simulations also prove the system scalability from a capacity perspective (e.g. to larger memory arrays) and from a technology perspective (e.g. to lower technology nodes).

The memory computing devices described herein can be based on conventional CMOS SRAMs, Flash memories, dynamic random access memories (DRAMs), resistive-based memories (like memristor-based memory arrays) or any other type of memories, including those using emerging technologies (e.g. RRAM, spin transfer torque (STT), spin orbit torque (SOT), spin orbit torque field effect transistor (SOTFET), ferroelectric field effect transistor (FeFET), . . . etc.).

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiments, whether alone or in any appropriate combination with any other feature disclosed or illustrated herein.

1. A memory computing device comprising:
a bitcell array comprising a plurality of bitcells, each bitcell being connected to a respective wordline and bitline;
an address decoder connected to the bitcell array; and
peripheral circuitry connected to the bitcell array, the peripheral circuitry comprising pre-charging and pre-discharging circuitry, sensing circuitry, write drivers and output circuitry;
wherein the address decoder is configured to receive an address for a wordline in the bitcell array and to activate the wordline corresponding to the address; and
wherein the peripheral circuitry is configured to:
pre-charge or pre-discharge a bitline in the bitcell array using the pre-charging and pre-discharging circuitry;
sense the bitline using the sensing circuitry;
receive a stochastic multiplier as input data for multiplication with read bitcell data in the bitcell array, wherein the read bitcell data constitutes a stochastic multiplicand;
perform, by the peripheral circuitry of the memory computing device, a digital stochastic multiplication between the input data and the read bitcell data; and
output a result of the stochastic multiplication.

2. The memory computing device of claim 1 wherein the peripheral circuitry is configured to mask the read bitcell data in the bitcell array to logic value 0 when the input data is 0.

3. The memory computing device of claim 1 wherein the pre-charging and pre-discharging circuitry is configured to perform the stochastic multiplication.

4. The memory computing device of claim 3 wherein the pre-charging and pre-discharging circuitry is configured to pre-discharge the bitline of the bitcell array such that the read bitcell data has a logic value 0 when the input data is 0.

5. The memory computing device of claim 3 wherein the peripheral circuitry is configured to pre-charge the bitline of the bitcell array for a conventional read operation, when the input data is 1.

6. The memory computing device of claim 1 wherein the sensing circuitry is configured to perform the stochastic multiplication.

7. The memory computing device of claim 6 wherein the sensing circuitry is configured to pull down the read bitcell data to logic value 0 when the input data is 0.

8. The memory computing device of claim 1 wherein the output circuitry is configured to perform the stochastic multiplication.

9. The memory computing device of claim 8 wherein the output circuitry is configured to reset the read bitcell data to logic value 0 when the input data is 0.

10. The memory computing device of claim 1 wherein the peripheral circuitry comprises one or more multiplexers operable to select a mode of operation of the memory computing device to one of a stochastic multiplication mode wherein the result of the stochastic multiplication is output and a conventional read mode wherein the read bitcell data in the bitcell array is output.

11. The memory computing device of claim 10 wherein the one or more multiplexers are operable to prevent the input data from being used for stochastic multiplication when the conventional read mode is selected.

12. A computer-implemented method of operating a memory computing device as a stochastic multiplier comprising:
performing a read operation on a bitcell array, the read operation comprising:
pre-charging a bitline in the bitcell array;
activating a wordline in the bitcell array; and
sensing the bitline;
receiving, in peripheral circuitry of the memory computing device, a stochastic multiplier as input data for multiplication with read bitcell data in the bitcell array, wherein the read bitcell data constitutes a stochastic multiplicand; and
performing, by the peripheral circuitry of the memory computing device, a digital stochastic multiplication between the input data and the read bitcell data; and
outputting a result of the stochastic multiplication.

13. The computer-implemented method of claim 12 wherein the memory computing device is in accordance with claim 1.

14. An artificial intelligence (AI) system comprising at least one memory computing device in accordance with claim 1.

15. A non-transitory computer-readable storage medium comprising instructions which, when executed by a computer cause the computer to perform the method of claim 12.
